(19) United States
(12) Patent Application Publication
(10) Pub. No.: US 2026/0354192 A1
(43) Pub. Date: Nov. 5, 2026

(54) WAFER-TO-WAFER BONDING HAVING EXHAUST PATHS AND RELATED METHODS

(71) Applicant: Taiwan Semiconductor Manufacturing Company Limited, Hsin-Chu (TW)

(72) Inventors: Tzu-Wei YU, Hsinchu City (TW); Kuo-Ming WU, Tainan City (TW); Ching I LI, Tainan (TW); Sheng-Chau CHEN, Tainan City (TW); Jian Yu CHEN, Chiayi City (TW); Chue San YOO, Hsin-Chu (TW)

(21) Appl. No.: 19/194,682

(22) Filed: Apr. 30, 2025

(51) Int. Cl. H10W 42/00; H10W 20/43; H10W 90/00

(52) U.S. Cl. CPC H10W 42/00; H10W 20/43; H10W 90/792

(57) ABSTRACT

A device is provided. The device includes: a first substrate; a first interconnect structure on the first substrate; a second substrate; a second interconnect structure on the second substrate, the first substrate being bonded to the second substrate by a hybrid bond between the first interconnect structure and the second interconnect structure; a via structure that extends through the first interconnect structure and the second interconnect structure; and a shield structure that is adjacent to the via structure. The shield structure includes: at least four walls on four respective sides of the via structure; and at least two openings in at least two respective walls of the at least four walls.

### BACKGROUND

Semiconductor devices are formed on, in, and/or from semiconductor wafers, and are used in a multitude of electronic devices, such as mobile phones, laptops, desktops, tablets, watches, gaming systems, and various other industrial, commercial, and consumer electronics. One or more semiconductor fabrication processes are performed to form semiconductor devices on, in, and/or from a semiconductor wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 1C, and 1D illustrate intermediate diagrammatic views of a method of forming an integrated circuit device, in accordance with some embodiments.

FIGS. 2A, 2B, 2C, 2D, 2E, 2F, and 2G illustrate diagrams of an integrated circuit device, in accordance with some embodiments.

FIGS. 3A, 3B, and 3C illustrate diagrams of an integrated circuit device, in accordance with some embodiments.

FIGS. 4A, 4B, 4C, 4D, and 4E illustrate diagrams of an integrated circuit device, in accordance with some embodiments.

FIGS. 5A, 5B, 5C, 5D, 5E, and 5F illustrate diagrams of an integrated circuit device, in accordance with some embodiments.

FIG. 6 is a flow diagram illustrating a method of forming an integrated circuit device, in accordance with some embodiments.

FIG. 7 is a flow diagram illustrating a method of forming an integrated circuit device, in accordance with some embodiments.

FIG. 8 illustrates an example computer-readable medium wherein processor-executable instructions configured to embody one or more of the provisions set forth herein may be comprised, according to some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

The term “overlying” and/or the like may be used to describe one element or feature being vertically coincident with and at a higher elevation than another element or feature. For example, a first element overlies a second element if the first element is at a higher elevation than the second element and at least a portion of the first element is vertically coincident with at least a portion of the second element.

The term “underlying” and/or the like may be used to describe one element or feature being vertically coincident with and at a lower elevation than another element or feature. For example, a first element underlies a second element if the first element is at a lower elevation than the second element and at least a portion of the first element is vertically coincident with at least a portion of the second element.

The term “over” may be used to describe one element or feature being at a higher elevation than another element or feature. For example, a first element is over a second element if the first element is at a higher elevation than the second element.

The term “under” may be used to describe one element or feature being at a lower elevation than another element or feature. For example, a first element is under a second element if the first element is at a lower elevation than the second element.

With progress in advanced semiconductor process nodes, wafer-on-wafer (WoW) processing technology, sometimes referred to as 3D wafer stacking, represents an advancement in semiconductor fabrication, allowing for increased transistor density and enhanced device performance. WoW involves stacking multiple wafers, either by directly bonding them or by using intermediate layers like through-silicon vias (TSVs), which are vertical electrical connections through the silicon. WoW processing provides benefits. By stacking wafers, more components can be integrated into a smaller footprint, effectively increasing the number of transistors or other elements per chip area. Reduced interconnect length due to vertical stacking leads to lower power consumption, faster signal transmission, and better overall performance due to decreased parasitic capacitance and inductance. Different types of chips, such as logic, memory, and sensors, can be integrated in a single package, allowing for improved performance characteristics associated with each technology. WoW processing enables formation of complex systems having multiple functionalities within the same package, which is beneficial for applications requiring high data throughput and energy efficiency. WOW processing technology is beneficial for forming advanced, compact, and efficient electronic devices, which may be included in computing, communications, and automotive electronics systems. One example device that can benefit from WoW processing is a complementary metal-oxide-semiconductor (CMOS) image sensor (CIS). The CIS can include a CMOS image sensing die and a logic or processing die that is stacked on the CMOS image sensing die.

When bonding two wafers to form a vertical wafer stack, a hybrid bond interface may be formed between two substantially smooth surfaces of the respective wafers, each of which can include, for example, a dielectric layer having conductive (e.g., metal) features embedded therein. The conductive features form metal bonds therebetween, forming electrical interconnection between circuitry of one of the wafers and circuitry of the other of the wafers.

In some wafers, it can be beneficial to include structures that protect components of one or both of the wafers. For example, a CIS device can include an array of millions of pixel circuits, each of which includes one or more pixel sensors or sub-pixel sensors in one integrated circuit (IC) die and logic circuitry in another IC die stacked thereto. Each of the pixel sensors may be isolated or partially isolated from adjacent pixel sensors by shielding structures, which can include, for example, a guard ring that reduces electromagnetic interference (EMI) therebetween. During WoW bonding, the guard rings that extend above the surface of one or both of the wafers can obstruct air flow across the surfaces being bonded together. As a result, air can be trapped or increase pressure at one or more of the pixels. In a later thermal process, such as an anneal, the high temperatures associated therewith can result in expansion of the air, which can result in bubbles, some of which can have dimensions that are orders of magnitude larger than dimensions of a single pixel sensor. For example, a 1.6-micron pixel sensor may be affected by bubbling having dimensions in a range of about 4 millimeters to 10 millimeters.

In embodiments of the disclosure, one or more exhaust paths are included in the shielding structure that improve ability of air to escape during WoW bonding and during following process operations, such as thermal processing. In some embodiments, each pixel sensor is laterally surrounded by four shield walls, and at least two of the shield walls define respective openings therein. The exhaust path(s) extend through the openings in the shield walls, resulting in reduction of air pressure and/or air trapping at the individual pixel sensors within the shield walls. As a result, bubbling is reduced, which improves yield and lifetime of the IC devices formed by the WoW process.

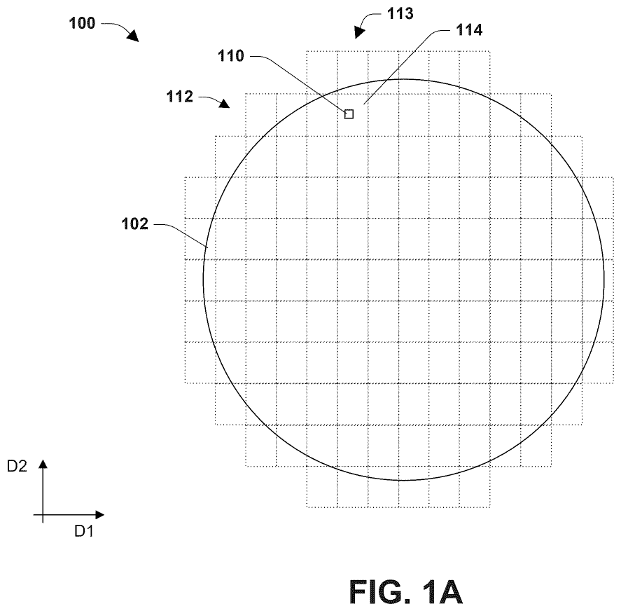

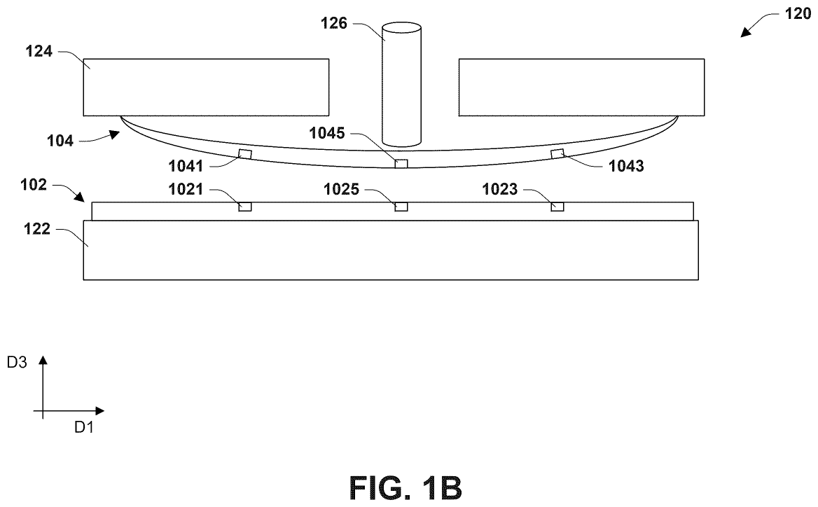

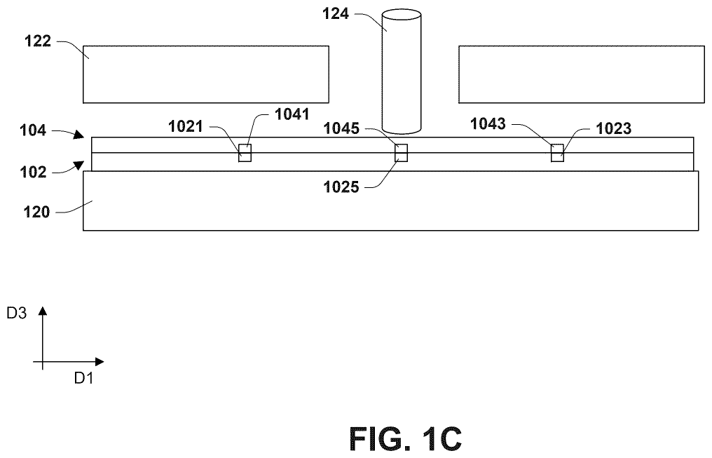

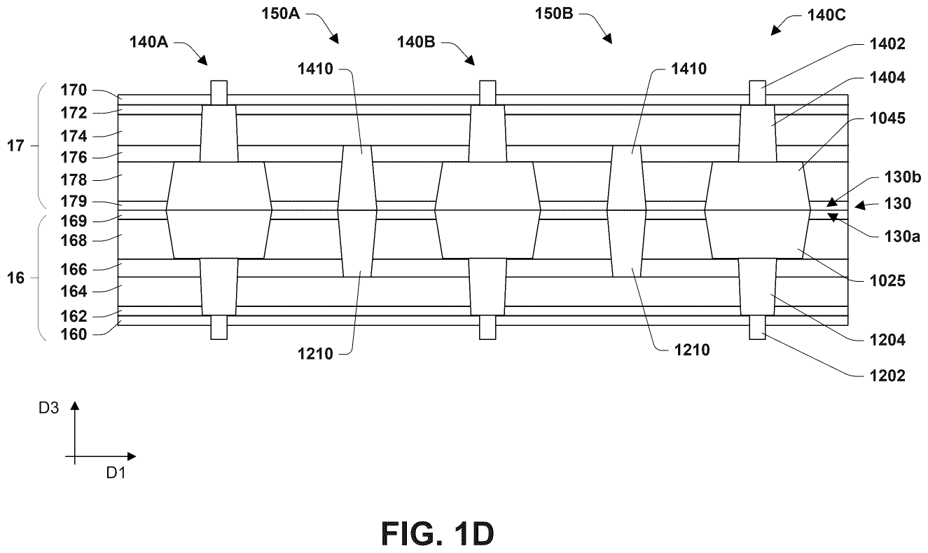

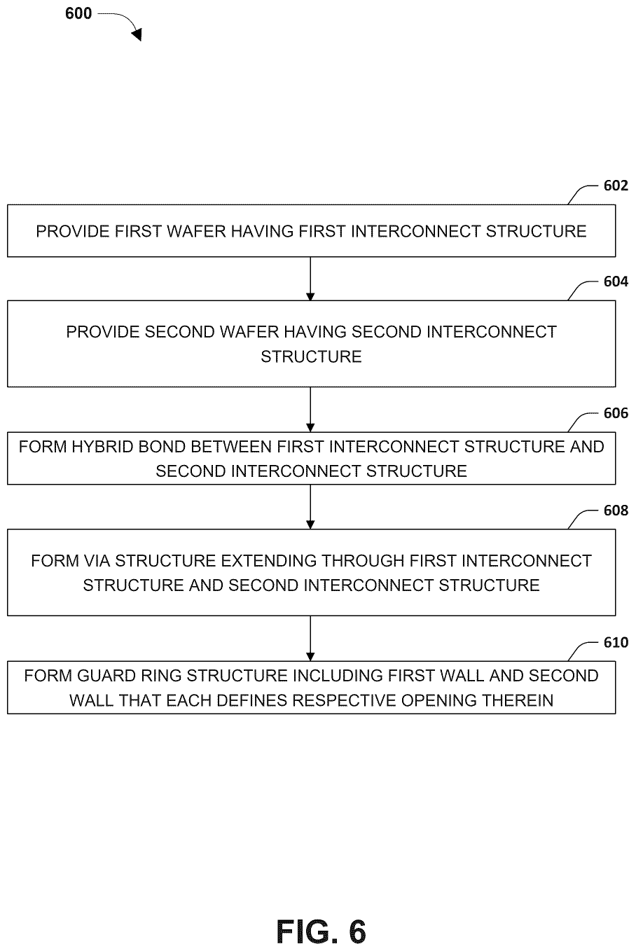

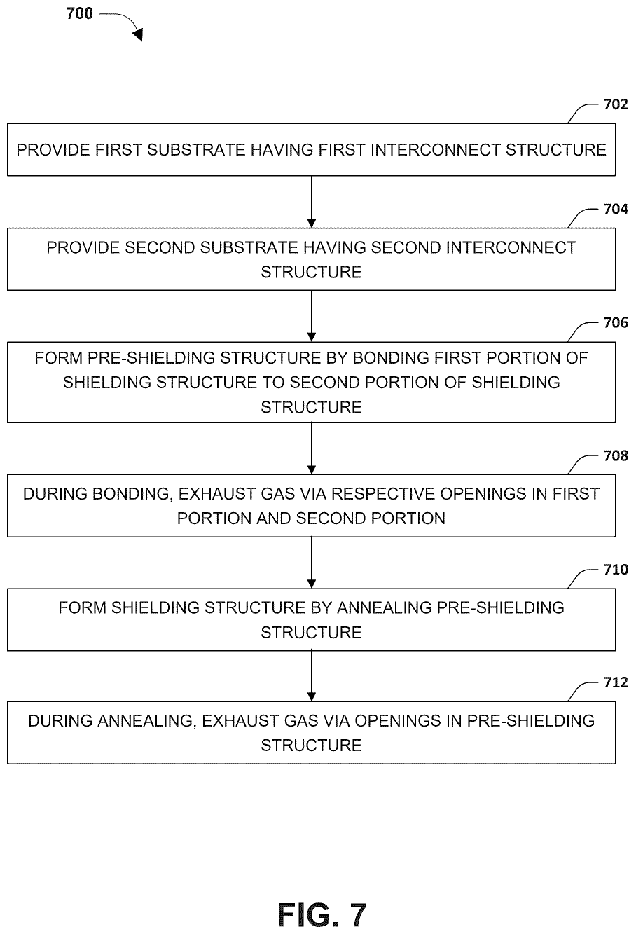

FIGS. 1A, 1B, 1C, and 1D illustrate intermediate diagrammatic views of a method of forming an integrated circuit device, in accordance with some embodiments. FIGS. 6 and 7 illustrate flow diagrams of some embodiments of methods 600, 700 for forming an integrated circuit device, in accordance with some embodiments.

While methods 600, 700 are illustrated and described below as series of acts or events, it will be appreciated that the illustrated ordering of such acts or events is not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

In FIG. 1A, an in-process IC wafer 100 (or simply “the first wafer 100”) is provided, corresponding to acts 602, 702 of FIGS. 6 and 7. The in-process IC wafer 100 can include an integrated circuit die region 110 positioned on and/or in a semiconductor substrate 102. In some embodiments, the in-process IC wafer 100 is formed by process operations, which can include patterning, deposition, cleaning, planarizing, annealing, epitaxial growing, and the like. The process operations form circuit features, such as metal gates, epitaxial source/drains, conductive vias, conductive traces, and the like.

In some embodiments, the semiconductor substrate 102 comprises at least one of a substrate, a photomask, a semiconductor device, a dielectric layer, an epitaxial layer, a silicon-on-insulator (SOI) structure, a semiconductor layer, a conductive material layer, a die, etc. The semiconductor substrate 102 comprises at least one of silicon, germanium, carbide, arsenide, gallium, arsenic, phosphide, indium, antimonide, SiGe, SIC, GaAs, GaN, GaP, InGaP, InP, InAs, InSb, GaAsP, AllnAs, AIGaAs, GalnAs, GalnP, GalnAsP, or other suitable material. The semiconductor substrate 102 comprises at least one of monocrystalline silicon, crystalline silicon with a <100> crystallographic orientation, crystalline silicon with a <110> crystallographic orientation, crystalline silicon with a <111> crystallographic orientation or other suitable material. Other structures and/or configurations of the semiconductor substrate 102 are within the scope of the present disclosure.

In some embodiments, the IC die regions 110 can be in-process dies or completed dies that are to be singulated in a subsequent process operation. The IC die regions 110 can be or include microcontrollers (MCUs), microprocessors (MPUs), graphics processing units (GPUs), artificial intelligence (AI) accelerators, memory ICs, analog ICs, logic ICs, optoelectronics, power management ICs, wireless communication ICs, image sensor ICs, image processing ICs, or the like. In some embodiments, the IC die regions 110 are arranged in one or more rows 112 and one or more columns 113. The rows 112 extend along a first direction D1 and are arranged along a second direction D2. The columns 113 extend along the second direction D2 and are arranged along the first direction D1. Each of the IC die regions 110 may be positioned in a photolithography field 114 that has size associated with a single exposure “shot” from a mask. The field 114 may include at least two IC die regions 110. For example, the field 114 may have dimensions of about 26 mm×33 mm and each of the IC die regions 110 may have dimensions of about 10 mm×10 mm or smaller. Other dimensions for the IC die regions 110 are also contemplated as embodiments herein.

In some embodiments, each of the IC die regions 110 includes one or more patterned layers of different materials that are arranged to form electronic circuits. Components of each IC die region 110 of the IC die regions 110 can include transistors, interconnects, capacitors, resistors, inductors, photodiodes, color filters and the like. The IC die region 110 can include many material layers, such as the substrate 102, epitaxial layers, isolation layers, gate dielectric layers, gate electrode layers, source/drain layers, contact layers, interconnect layers, dielectric layers, passivation layers and the like. Formation of the material layers can include performing one or more semiconductor processes, such as deposition, photolithography, etching/patterning, doping/implantation, planarization and the like. Along a vertical axis that is perpendicular to the major surface of the IC die region 110, from bottom to top, the IC die region 110 can include a device region and an interconnect region on the device region. The device region can generally include the transistors and capacitors, and the interconnect region can generally include the interconnects as well as capacitors, inductors, resistors and the like. The transistors can be or include field effect transistors (FETs), which can include planar transistors, fin FETs (or “FinFETs”), nanostructure FETs (e.g., nanosheet FETs or the like), vertical FETs, and the like. In some embodiments, the interconnect region can include memory devices, such as phase-change random access memory (PCRAM) devices, magnetoresistive random access memory (MRAM) devices, and/or other suitable memory devices.

In some embodiments, prior to bonding the first wafer 100 to a second wafer in a subsequent operation, an interconnect structure or redistribution layer (RDL) structure may be formed on an active surface of the first wafer 100. For example, the first wafer 100 may include a device layer having transistors positioned therein, and may further include a first interconnect structure on the device layer having front-end-of-line (FEOL) interconnects, mid-end-of-line (MEOL) interconnects and back-end-of-line (BEOL) interconnects. The RDL structure may be formed on the BEOL interconnects, such as on a top metal layer of the BEOL interconnects. The RDL structure may include at least two dielectric layers having metallization features (e.g., vias and traces) embedded therein. A top metal layer of the RDL structure may include active pads or active contacts for forming signal connections with the second wafer. The top metal layer of the RDL structure may include first alignment features, which may be first conductive features. Following bonding, the first alignment features may directly overlap second alignment features of the second wafer. Alignment accuracy may be determined based on accuracy of the overlap between the first and second alignment features. Each pair of overlapping first and second alignment features may be referred to collectively as an alignment mark. Each integrated circuit die region 110 may include an alignment pattern that has at least four alignment marks. Namely, when a single mask exposure is associated with an entire integrated circuit die region 110, each single mask exposure can include an alignment pattern that includes the at least four alignment marks. In some embodiments, at least two of the alignment marks are intra-field alignment marks, meaning that the alignment marks are formed in an active circuit region of the IC die region 110 instead of in a periphery of the IC die region 110 or in a scribe line surrounding the IC die region 110.

In FIG. 1B, a second wafer 104 (or “second substrate”) is provided, corresponding to acts 604, 704 of FIGS. 6 and 7, and the second wafer 104 is bonded to the first wafer 102, corresponding to acts 606, 706 of FIGS. 6 and 7.

The second wafer 104 can be similar in some respects to the first wafer 102, but may include different circuitry or different components than those of the first wafer 102. As one non-limiting example, the first wafer 102 may be bonded to the second wafer 104 to form a complementary metal-oxide-semiconductor (CMOS) image sensor (CIS). In this example, the second wafer 104 may include a backside illumination (BSI) image sensor and the first wafer 102 may include readout and controller circuitry, image processing circuitry, digital signal processor (DSP) circuitry, and the like. Formation of the second wafer 104 may include process operations similar to those described with reference to FIG. 1A, such as etching, deposition, cleaning, planarization, epitaxial growth, and the like.

During bonding, the first wafer 102 may be bonded to the second wafer 104 by a bonding apparatus 120. The bonding apparatus 120 may include a first stage 122, a second stage 124, and a press 126. The first wafer 102 is supported and/or held by the first stage 122. The second wafer 104 is supported and/or held by the second stage 124. The press 126 may be operable to translate the second stage 124 toward the first stage 122 along a third direction D3 (or “vertical direction D3”) to press the first and second wafers 102, 104 together.

In operation, the bonding apparatus 120 can include one or more high-precision alignment mechanisms, such as optical or mechanical structures that improve alignment of via portions 1021, 1041, 1023, 1043, 1025, 1045 of RDL structures of the first and second wafers 102, 104. The bonding apparatus 120 can apply substantially uniform pressure across surfaces of the first and second wafers 102, 104. For hybrid bonding, dielectric-to-dielectric bonds form initially, then metal-to-metal (e.g., copper-to-copper) bonds form during an annealing operation. The bonding apparatus 120 can include heating capabilities to reach temperatures beneficial for the annealing operation, which is beneficial for hybrid bonding. Temperatures can range from room temperature for initial bonding to around 200 °C to 300 °C or higher for metal diffusion and solidification. In some embodiments, prior to bonding, surfaces of the first and second wafers 102, 104, especially the RDL, are prepared to be flat and clean, which can include performing chemical mechanical polishing (CMP). To prevent contamination, which can result in void formation or bonding defects, the bonding apparatus 120 can operate in a cleanroom environment or under controlled atmospheric conditions.

During formation of a dielectric bond, oxide layers on the first and second wafers 102, 104 can come into contact with each other and form a weak bond at room or slightly elevated temperatures. Then, the first and second wafers 102, 104 are heated to allow the via portions 1021, 1041, 1023, 1043, 1025, 1045 to expand, resulting in the structure depicted in FIG. 1C. Although not separately depicted in FIG. 1B, other conductive pads may be included in the first and second wafers 102, 104 that, during bonding, expand, come into contact with each other and form strong metallic bonds through diffusion.

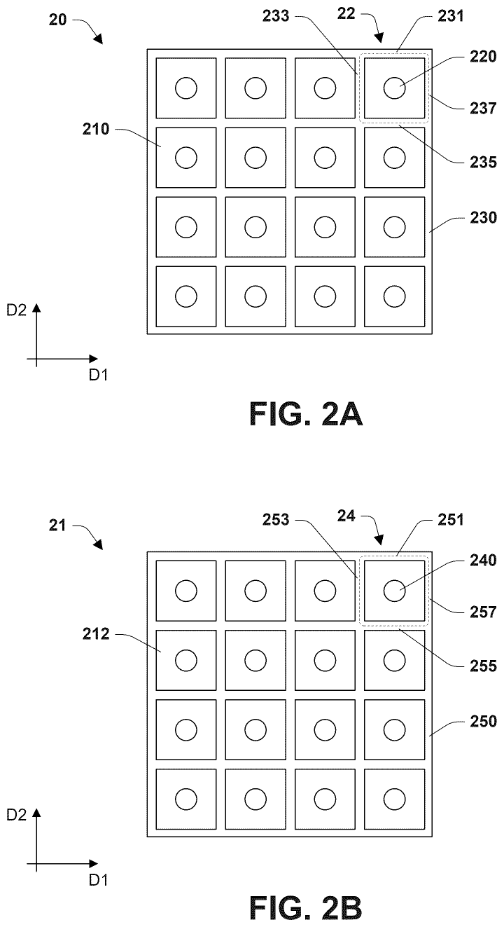

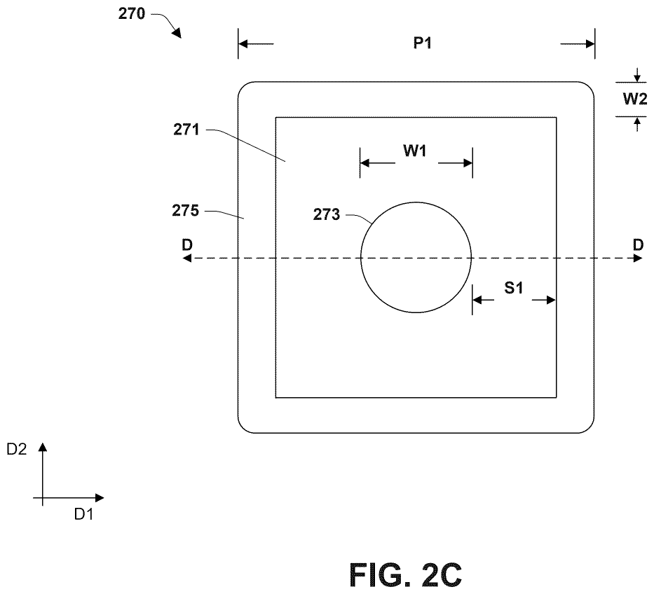

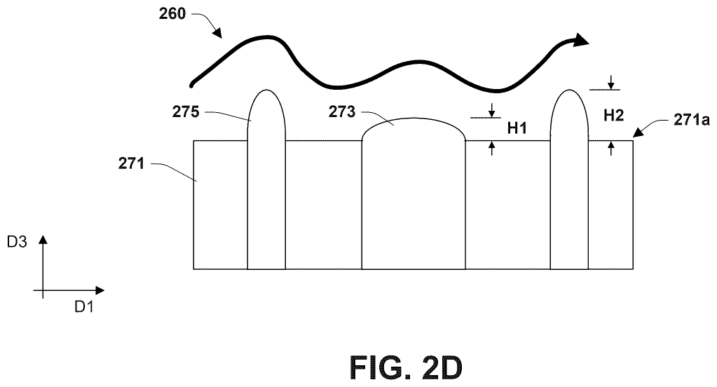

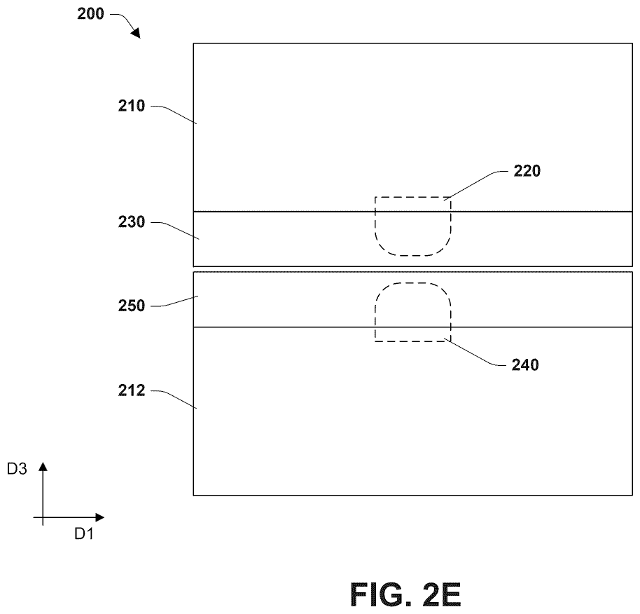

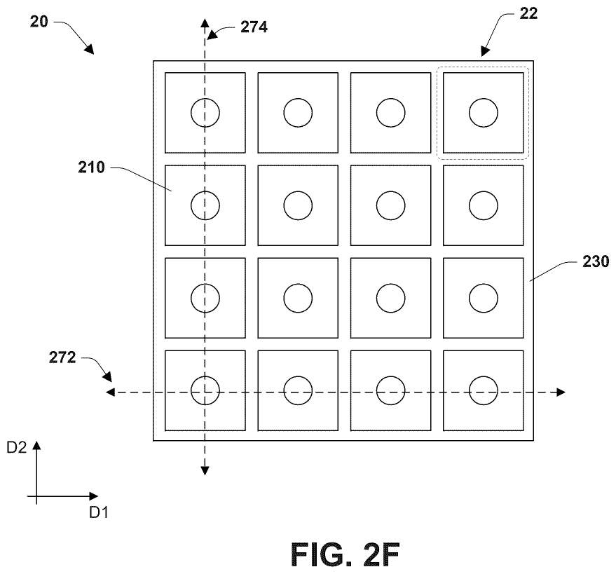

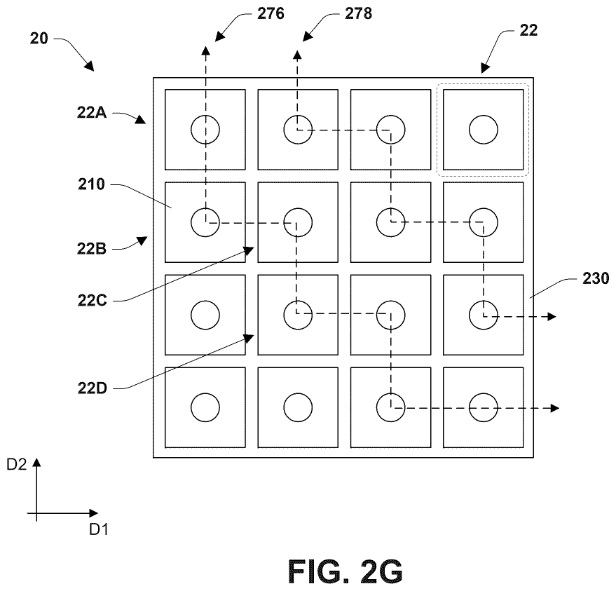

As will be described with reference to FIGS. 2A-5F, a shield structure that laterally surrounds pixels or other array elements of the first and second wafers 102, 104, such as a guard ring structure, can extend somewhat above the surface(s) of the first and/or second wafers 102, 104, which can result in reduction of air flow and outgassing during bonding and annealing. In some embodiments, one or more exhaust paths are included in the shield structure that improve outgassing, which can reduce bubbling during bonding, annealing, or both.

In FIG. 1C, the first and second wafers 102, 104 are bonded to each other. As depicted, first via portions 1021, 1023, 1025 of the first wafer 102 may be bonded to second via portions 1041, 1043, 1045 of the second wafer 104, respectively, after bonding. For example, the first via portion 1021 and the corresponding second via portions 1041 are bonded together to form a via structure.

FIG. 1D depicts a view of via structures 140A, 140B, 140C that are isolated from each other (e.g., partially or fully) by guard ring structures 150A, 150B.

In FIG. 1D, a first interconnect structure 16 of or on the first wafer 102 is bonded to a second interconnect structure 17 of or on the second wafer 104. A hybrid bond interface 130 is formed at a first surface 130a of the first interconnect structure 16 and at a second surface 130b of the second interconnect structure 17. In some embodiments, a pre-bond interface is formed by pressing the first surface 130a to the second surface 130b, then a bonding interface or hybrid bond interface 130 is formed by annealing. In some embodiments, annealing is omitted.

The hybrid bond interface 130 can include connections between conductive portions and dielectric or insulator portions of the first interconnect structure 16 and the second interconnect structure 17. For example, upper via portions 1025, 1045 of the first interconnect structure 16 and the second interconnect structure 17 can have a conductive or metal bond therebetween at the hybrid bond interface 130. In another example, top dielectric layers 169, 179 of the first interconnect structure 16 and the second interconnect structure 17 can have a dielectric bond therebetween at the hybrid bond interface 130.

Each respective first via portion of the via structures 140A, 140B, 140C of the first interconnect structure 16 can include one or more of a first via feature 1202, a second via feature 1204, the upper via portion 1025, and the like. In some embodiments, the upper via portion 1025 has dimension in the first direction D1 that exceeds that of the second via feature 1204, which exceeds that of the first via feature 1202. The upper via portion 1025 is positioned on (e.g., in direct contact with) the second via feature 1204, which is positioned on (e.g., in direct contact with) the first via feature 1202. In some embodiments, the first via feature 1202, the second via feature 1204 and the upper via portion 1025 include the same material or a different material, which can be one or more of copper, nickel, aluminum, tungsten, ruthenium, cobalt, combinations thereof or the like, which can be formed by sputtering (PVD), electroplating, electroless plating or the like.

Each respective second via portion of the via structures 140A, 140B, 140C of the second interconnect structure 17 can include one or more of a first via feature 1402, a second via feature 1404, the upper via portion 1045, and the like. In some embodiments, the upper via portion 1045 has dimension in the first direction D1 that exceeds that of the second via feature 1404, which exceeds that of the first via feature 1402. The upper via portion 1045 is positioned on (e.g., in direct contact with) the second via feature 1404, which is positioned on (e.g., in direct contact with) the first via feature 1402. In some embodiments, the first via feature 1402, the second via feature 1404 and the upper via portion 1045 include the same material or a different material, which can be one or more of copper, nickel, aluminum, tungsten, ruthenium, cobalt, combinations thereof or the like, which can be formed by sputtering (PVD), electroplating, electroless plating or the like.

In some embodiments, the first interconnect structure 16 and the second interconnect structure 17 are each redistribution layer (RDL) structures that are positioned on respective BEOL interconnect structures of the first wafer 102 and the second wafer 104, respectively. For example, the first via features 1202, 1402 can be top metal features of the respective BEOL interconnect structures.

The first via features 1202, 1402 extend into and/or through first dielectric layers 160, 170 of the first interconnect structure 16 and the second interconnect structure 17, respectively.

The second via features 1204, 1404 extend into and/or through second dielectric layers 162, 172, third dielectric layers 164, 174 and fourth dielectric layers 166, 176 of the first interconnect structure 16 and the second interconnect structure 17, respectively.

The upper via portions 1025, 1045 extend into and/or through fifth dielectric layers 168, 178 and sixth dielectric layers 169, 179 of the first interconnect structure 16 and the second interconnect structure 17, respectively.

In some embodiments, the upper via portions 1025, 1045 and the second via features 1204, 1404 have tapered sidewalls that have increased dimension proximal the hybrid bond interface 130.

Each of the first dielectric layers 160, 170, the second dielectric layers 162, 172, the third dielectric layers 164, 174, the fourth dielectric layers 166, 176, the fifth dielectric layers 168, 178 and the sixth dielectric layers 169, 179 can be or include the same or different dielectric material, which can be or include one or more of SiO, SiN, SiON, SiC, SiOC, SiOCN, tetraethoxysilane (TEOS) oxide, phosphosilicate glass (PSG), borophosphosilicate glass (BPSG), low-k dielectric material, and/or another applicable dielectric material. Examples of low-k dielectric materials include, fluorinated silica glass (FSG), carbon doped silicon oxide, amorphous fluorinated carbon, parylene, bis-benzocyclobutenes (BCB), polybenzoxazole (PBO) or polyimide. In some embodiments, the dielectric material is formed by chemical vapor deposition (CVD), physical vapor deposition (PVD), atomic layer deposition (ALD), spin-on coating, or another applicable process.

The guard ring structures 150A, 150B each include a first portion 1210 in the first interconnect structure 16 and a second portion 1410 in the second interconnect structure 17. In some embodiments, each of the first portion 1210 and the second portion 1410 is or includes copper, aluminum, heavily-doped polysilicon, or the like. In some embodiments, material of the guard ring structures 150A, 150B is the same as that of the via structures 140A, 140B, 140C. For example, the first portion 1210 may be formed in a same operation that forms the upper via portion 1025. Similarly, the second portion 1410 may be formed in a same operation that forms the upper via portion 1045.

In some embodiments, the guard ring structure 150A and the guard ring structure 150B are each respective guard ring walls of a single guard ring that encircles or laterally surrounds the via structure 140B. For example, the guard ring structure 150A can be a first side (e.g., left side) wall, the guard ring structure 150B can be a second side (e.g., right side) wall, and additional front and back side walls can extend from the first side wall to the second side wall on front and back sides of the via structure 140B. In some embodiments, the guard ring structures 150A, 150B have tapered sidewalls that have increased dimension proximal the hybrid bond interface 130. In some embodiments, width of the guard ring structure 150A and the guard ring structure 150B in the first direction D1 is in a range of about 50 nanometers to about 500 nanometers, such as about 200 nanometers or another suitable width. In some embodiments, width of the upper via portion 1025 and the upper via portion 1045 in the first direction D1 is in a range of about 100 nanometers to about 1000 nanometers, such as about 350 nanometers or another suitable width. In some embodiments, the width of the upper via portions 1025, 1045 exceeds the width of the guard ring structures 150A, 150B. In some embodiments, separation between the guard ring structures 150A, 150B and the upper via portions 1025, 1045 along the first direction D1 is in a range of about 200 nanometers to about 800 nanometers, such as about 425 nanometers or another suitable separation.

During bonding of the first portion 1210 of the guard ring structures 150A, 150B to the second portion 1410 of the guard ring structures 150A, 150B, air or gas is in the environment (e.g., a processing chamber) in which the first wafer 102 is bonded to the second wafer 104. Trapping the air or gas by the guard ring structures 150A, 150B can result in bubbling either during pre-bonding or during an anneal that forms the hybrid bond interface 130. The bubbling can result in failure of a device (e.g., CIS) in which the bubbling is present. In the embodiments, as described with reference to FIGS. 2A-8, exhaust paths are present in a shielding structure that includes the guard ring structures 150A, 150B. The exhaust paths include openings in guard ring walls, such as the guard ring structures 150A, 150B, which improves outgassing and reduces bubbling, both in quantity and severity of bubbling. As a result, manufacturing yield and device reliability are increased dramatically.

FIGS. 2A, 2B, 2C, 2D, 2E, 2F, and 2G illustrate diagrams of an integrated circuit (IC) device 200, in accordance with some embodiments.

FIGS. 2A and 2B illustrate a first wafer 20 and a second wafer 21 of the IC device 200. The first wafer 20 and the second wafer 21 can be a top wafer and a bottom wafer of a WoW structure.

In FIG. 2A, the first wafer 20 includes a first substrate 210, which can be similar in most respects to the semiconductor substrate or “first wafer” 102. The first wafer 102 can be an embodiment of the first wafer 20. In some embodiments, the first wafer 20 includes a plurality of array structure portions or pixel portions 22 positioned therein, thereon or both. The pixel portions 22 can be arranged in pixel rows that extend along the first direction D1 and are arranged along the second direction D2. The pixel portions 22 can be arranged in pixel columns that extend along the second direction D2 and are arranged along the first direction D1. Each of the pixel portions 22 includes a respective via structure portion 220 therein.

A first shielding structure portion 230 is positioned on and/or in the substrate 210. Each of the pixel portions 22 can include a first shield wall portion 231, a second shield wall portion 233, a third shield wall portion 235 and a fourth shield wall portion 237 of the first shielding structure portion 230, which can be referred to collectively as the shield wall portions 231, 233, 235, 237. Each of the shield wall portions 231, 233, 235, 237 can be positioned between an immediately adjacent pair of the pixel portions 22.

The second wafer 21 includes a second substrate 212, which can be similar in most respects to the semiconductor substrate or “second wafer” 104. The second wafer 104 can be an embodiment of the second wafer 21. In some embodiments, the second wafer 21 includes a plurality of array structure portions or pixel portions 24 positioned therein, thereon or both. The pixel portions 24 can be arranged in pixel rows that extend along the first direction D1 and are arranged along the second direction D2. The pixel portions 24 can be arranged in pixel columns that extend along the second direction D2 and are arranged along the first direction D1. Each of the pixel portions 24 includes a respective via structure portion 240 therein.

A second shielding structure portion 250 is positioned on and/or in the substrate 212. Each of the pixel portions 24 can include a first shield wall portion 251, a second shield wall portion 253, a third shield wall portion 255 and a fourth shield wall portion 257 of the second shielding structure portion 250, which can be referred to collectively as the shield wall portions 251, 253, 255, 257. Each of the shield wall portions 251, 253, 255, 257 can be positioned between an immediately adjacent pair of the pixel portions 24.

Similar to described with reference to FIGS. 1A-1D, the first wafer 20 is bonded to the second wafer 21. After bonding, each of the pixel portions 22 is bonded to a corresponding pixel portion 24, each of the via portions 220 is bonded to a corresponding via portion 240, and the first shielding structure portion 230 is bonded to the second shielding structure portion 250. In some embodiments, the first shield wall portions 231, 251 are bonded to each other, the second shield wall portions 233, 253 are bonded to each other, the third shield wall portions 235, 255 are bonded to each other, and the fourth shield wall portions 237, 257 are bonded to each other.

FIG. 2C illustrates a diagram of a pixel portion 270, in accordance with some embodiments, which is an embodiment of the pixel portion 22, the pixel portion 24, or both.

In FIG. 2C, the pixel portion 270 is formed on or in a substrate 271, which is similar in most respects to the first wafer 102 or the second wafer 104 and the substrates 210, 212 described with reference to FIGS. 1A-1D, 2A, and 2B. The pixel portion 270 includes a via structure 273, which is similar in most respects to the that described with reference to FIG. 1D. The pixel portion 270 includes a shielding structure portion 275, which can be similar in most respects to the first and second shielding structure portions 230, 250 described with reference to FIGS. 2A and 2B.

Dimensions of the pixel portion 270 are depicted in FIG. 2C. In FIG. 2C, in some embodiments, width W2 of the shielding structure portion 275 in the first direction D1 and/or the second direction D2 is in a range of about 50 nanometers to about 500 nanometers, such as about 200 nanometers or another suitable width. In some embodiments, width or diameter W1 of the via structure 273 in the first direction D1 and/or the second direction D2 is in a range of about 100 nanometers to about 1000 nanometers, such as about 350 nanometers or another suitable width.

In some embodiments, the width W1 exceeds the width W2. In some embodiments, separation S1 between the shielding structure portion 275 and the via structure 273 along the first direction D1 and/or the second direction D2 is in a range of about 200 nanometers to about 800 nanometers, such as about 425 nanometers or another suitable separation S1.

FIG. 2D illustrates a diagram of the pixel portion 270 along line D-D of FIG. 2C, in accordance with some embodiments.

In FIG. 2D, the via structure 273 may extend above an upper surface 271a of the substrate 271 by a first height H1 along the third direction D3, and the shielding structure portion 275 may extend above the upper surface 271a by a second height H2 along the third direction D3 that exceeds the first height H1. In some embodiments, the second height H2 exceeds the first height H1 by a range of about 1 Angstrom to about 5 Angstroms, such as about 2 Angstroms. As a result, during bonding, air or gas flowing across the upper surface 271a may be obstructed by the shielding structure portion 275 more than by the via structure 273, as depicted by arrow 260 in FIG. 2D. Namely, the flow or exhausting of the air or gas may be slowed by the shielding structure portion 275, which can increase trapping of the air or gas during WoW bonding.

In FIG. 2E, the shielding structure portion 230 is bonded to the shielding structure portion 250 by translating the shielding structure portion 230 toward the shielding structure portion 250. The via portions 220, 240 are depicted in phantom and are similarly bonded by translating the via portion 220 toward the via portion 240.

In FIGS. 2F and 2G, to reduce or eliminate trapping of gas or air between the first shielding structure portion 230 and the second shielding structure portion 250 during bonding, a subsequent anneal or both, exhaust paths 272, 274, 276, 278 are positioned in the first shielding structure portion 230, the second shielding structure portion 250 or both.

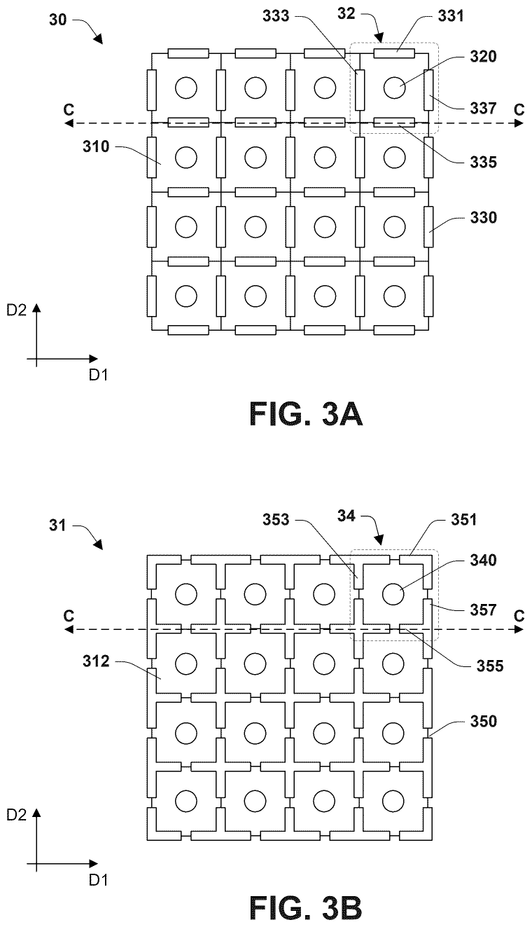

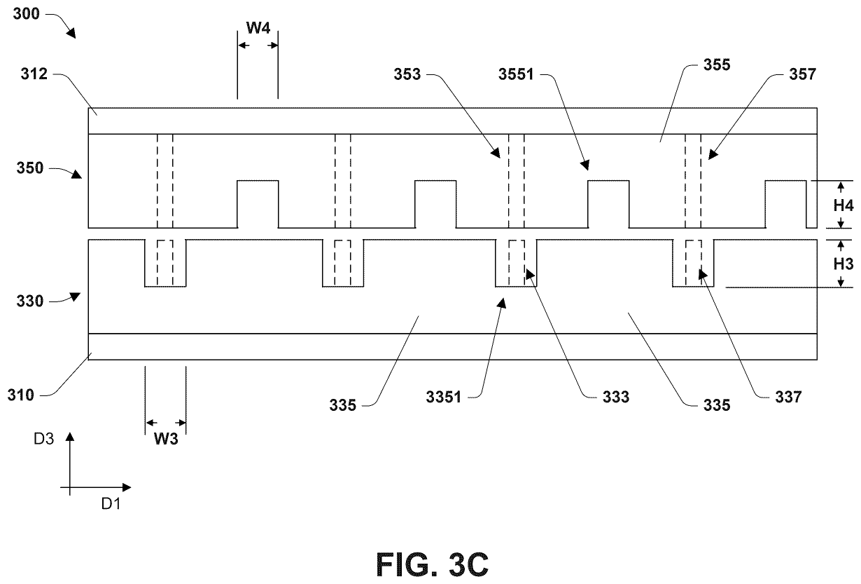

In FIG. 2F, a first exhaust path 272 extends along the first direction D1 and a second exhaust path 274 extends along the second direction D2. Two exhaust paths 272, 274 are depicted in FIG. 2F for simplicity of illustration. In some embodiments, each pixel row can include a first exhaust path 272 and each pixel column can include a second exhaust path 274. It should be understood that the first exhaust path 272 and the second exhaust path 274 can be present in the first shielding structure portion 230, the second shielding structure portion 250 or both. Although not separately illustrated in FIG. 2F for clarity of illustration, the first exhaust path 272 and the second exhaust path 274 may extend through openings defined in the first shielding structure portion 230, the second shielding structure portion 250 or both. Embodiments of the openings are described with reference to FIGS. 3A-5F.

In the embodiments illustrated by FIG. 2G, a first exhaust path 276 and a second exhaust path 278 are depicted. Two exhaust paths 276, 278 are depicted in FIG. 2G for simplicity of illustration. In some embodiments, additional exhaust paths may be included such that each pixel has at least one exhaust path running therethrough. It should be understood that the first exhaust path 276 and the second exhaust path 278 can be present in the first shielding structure portion 230, the second shielding structure portion 250 or both.

The first exhaust path 276 is described in detail. The second exhaust path 278 is similar in most respects to the first exhaust path 276 and is not described in detail for brevity.

The first exhaust path 276 can extend along the first direction D1 and the second direction D2, as shown. For example, starting from a first pixel portion 22A, the first exhaust path 276 can extend through the first pixel portion 22A to a second pixel portion 22B that is immediately adjacent to the first pixel portion 22A along the second direction D2. Then, the first exhaust path 276 can extend through the second pixel portion 22B to a third pixel portion 22C that is immediately adjacent to the second pixel portion 22B along the first direction D1. Then, the first exhaust path 276 can extend through the third pixel portion 22C to a fourth pixel portion 22D that is immediately adjacent to the third pixel portion 22C along the second direction D2, and so on. Namely, the first exhaust path 276 can extend alternately along the first direction D1, then the second direction D2, then the first direction D1, then the second direction D2, and so on. As a result, each of the pixel portions 22A, 22B, 22C, 22D may have openings in two of four side walls of the first shielding structure portion 230 immediately adjacent thereto. This can reduce number of openings in the first shielding structure portion 230.

FIGS. 3A, 3B, and 3C illustrate diagrams of an integrated circuit device 300, in accordance with some embodiments. The integrated circuit device 300 can be an embodiment of the integrated circuit device 200 described with reference to FIGS. 2A-2G. Similar elements can be labeled with similar reference numerals. For example, a pixel portion 32 and the pixel portion 22 may be similar elements, a first shielding structure portion 330 and the first shielding structure portion 230 may be similar elements, and so on.

In FIG. 3A, a first wafer 30 includes a first substrate 310, which can be similar in most respects to the semiconductor substrate or “first wafer” 102. The first wafer 102 can be an embodiment of the first wafer 30. In some embodiments, the first wafer 30 includes a plurality of array structure portions or pixel portions 32 positioned therein, thereon or both. The pixel portions 32 can be arranged in pixel rows that extend along the first direction D1 and are arranged along the second direction D2. The pixel portions 32 can be arranged in pixel columns that extend along the second direction D2 and are arranged along the first direction D1. Each of the pixel portions 32 includes a respective via structure portion 320 therein.

A first shielding structure portion 330 is positioned on and/or in the substrate 310. Each of the pixel portions 32 can include a first shield wall portion 331, a second shield wall portion 333, a third shield wall portion 335 and a fourth shield wall portion 337 of the first shielding structure portion 330, which can be referred to collectively as the shield wall portions 331, 333, 335, 337. Each of the shield wall portions 331, 333, 335, 337 can be positioned between an immediately adjacent pair of the pixel portions 32.

The second wafer 31 includes a second substrate 312, which can be similar in most respects to the semiconductor substrate or “second wafer” 104. The second wafer 104 can be an embodiment of the second wafer 31. In some embodiments, the second wafer 31 includes a plurality of array structure portions or pixel portions 34 positioned therein, thereon or both. The pixel portions 34 can be arranged in pixel rows that extend along the first direction D1 and are arranged along the second direction D2. The pixel portions 34 can be arranged in pixel columns that extend along the second direction D2 and are arranged along the first direction D1. Each of the pixel portions 34 includes a respective via structure portion 340 therein.

A second shielding structure portion 350 is positioned on and/or in the substrate 312. Each of the pixel portions 34 can include a first shield wall portion 351, a second shield wall portion 353, a third shield wall portion 355 and a fourth shield wall portion 357 of the second shielding structure portion 350, which can be referred to collectively as the shield wall portions 351, 353, 355, 357. Each of the shield wall portions 351, 353, 355, 357 can be positioned between an immediately adjacent pair of the pixel portions 34.

Similar to described with reference to FIGS. 1A-1D, the first wafer 30 is bonded to the second wafer 31. After bonding, each of the pixel portions 32 is bonded to a corresponding pixel portion 34, each of the via portions 320 is bonded to a corresponding via structure portion 340, and the first shielding structure portion 330 is bonded to the second shielding structure portion 350. In some embodiments, the first shield wall portions 331, 351 are bonded to each other, the second shield wall portions 333, 353 are bonded to each other, the third shield wall portions 335, 355 are bonded to each other, and the fourth shield wall portions 337, 357 are bonded to each other.

FIGS. 3A and 3B depict that each of the first shielding structure portion 330 and the second shielding structure portion 350 has height that is not continuous. For example, in FIG. 3A, corner regions of the first shielding structure portion 330 that are adjacent four of the pixel portions 32 have reduced height relative to side regions of the first shielding structure portion 330 that are adjacent two of the pixel portions 32. In another example, in FIG. 3B, side regions of the second shielding portion 350 have at least one portion having reduced height compared to height of corner regions of the second shielding portion 350. This is depicted in and described with reference to FIG. 3C, which is a view along line C-C of FIGS. 3A and 3B.

In FIG. 3C, the integrated circuit device 300 includes the first shielding structure portion 330 that has first openings 3351 defined therein and the second shielding structure portion 350 that has second openings 3551 defined therein. As described with reference to FIGS. 3A and 3B, the first openings 3351 may be defined at corner regions of the first shielding structure portion 330. For example, respective first openings 3351 may be aligned with and overlap the second shield wall portion 333 and the fourth shield wall portion 337, which are depicted in phantom in FIG. 3C. The first openings 3351 may be defined in immediately adjacent third shield wall portions 335.

The first openings 3351 have first width W3 and first height H3 in the first direction D1 and the third direction D3, respectively. In some embodiments, the first height H3 does not exceed height of the first shielding structure portion 330. Namely, the first openings 3351 may extend partially through the first shielding structure portion 330 and may not extend fully through the first shielding structure portion 330 to expose the underlying first substrate 310.

As described with reference to FIGS. 3A and 3B, the second openings 3551 may be defined at side regions of the second shielding structure portion 350. For example, respective second openings 3551 may be offset from and be positioned between (e.g., not overlap) the second shield wall portion 353 and the fourth shield wall portion 357, which are depicted in phantom in FIG. 3C. The second openings 3551 may be defined in each respective third shield wall portion 355.

The second openings 3551 have second width W4 and second height H4 in the first direction D1 and the third direction D3, respectively. In some embodiments, the second height H4 does not exceed height of the second shielding structure portion 350. Namely, the second openings 3551 may extend partially through the second shielding structure portion 350 and may not extend fully through the second shielding structure portion 350 to expose the underlying second substrate 312.

In some embodiments, the first height H3 and the second height H4 are substantially the same or can be different. For example, the first height H3 can exceed the second height H4 or the second height H4 can exceed the first height H3.

In some embodiments, the first width W3 and the second width W4 are substantially the same or can be different. For example, the first width W3 can exceed the second width W4 or the second width W4 can exceed the first width W3.

In some embodiments, first aspect ratio of the first height H3 over the first width W3 can be in a range of about 0.0001 to about 0.1, such as about 0.001 to about 0.01 or another suitable range. For example, the first height H3 may be less than about 1 nanometer or 10 Angstroms, and the first width W3 may exceed about 100 nanometers, such as being about 500 nanometers. In some embodiments, second aspect ratio of the second height H4 over the second width W4 can be in a range of about 0.0001 to about 0.1, such as about 0.001 to about 0.01 or another suitable range. In some embodiments, the first aspect ratio and the second aspect ratio have substantially the same value as or different value than each other.

In some embodiments, the first openings 3351 are omitted or the second openings 3551 are omitted. Generally, the first openings 3351 are present, the second openings 3551 are present, or both.

Including the first openings 3351, the second openings 3551, or both can be beneficial to increase outgassing during bonding, subsequent annealing or both, which can improve yield and reliability.

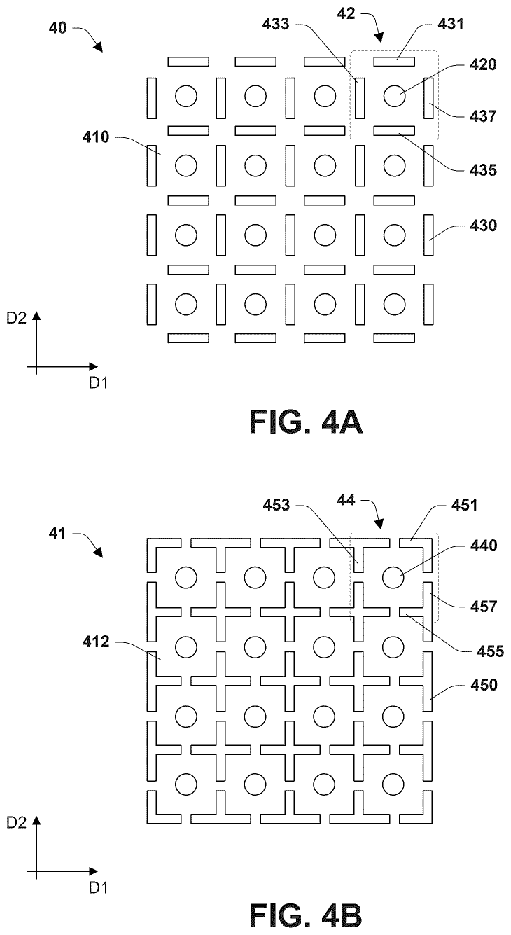

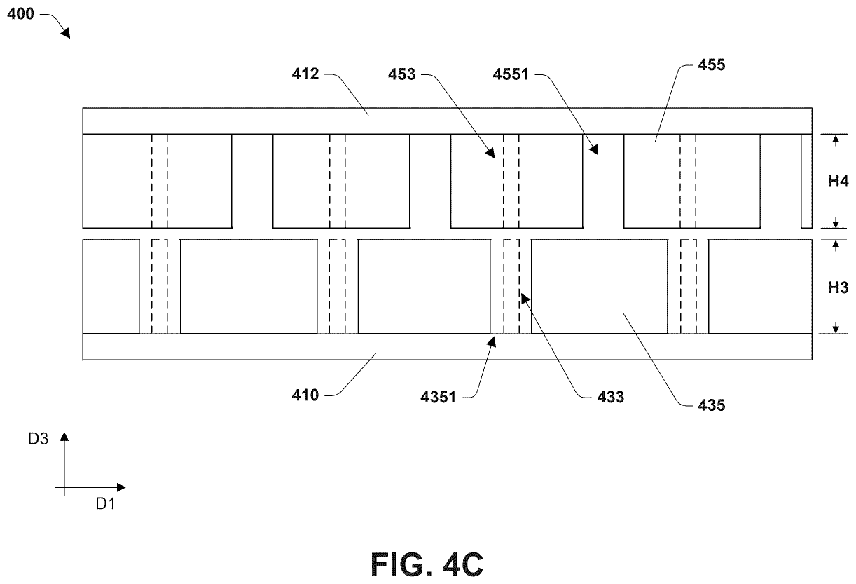

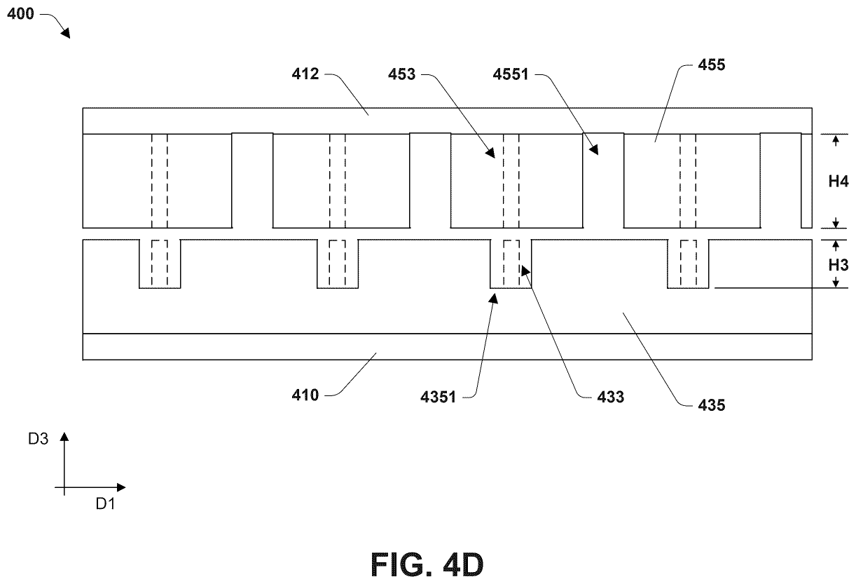

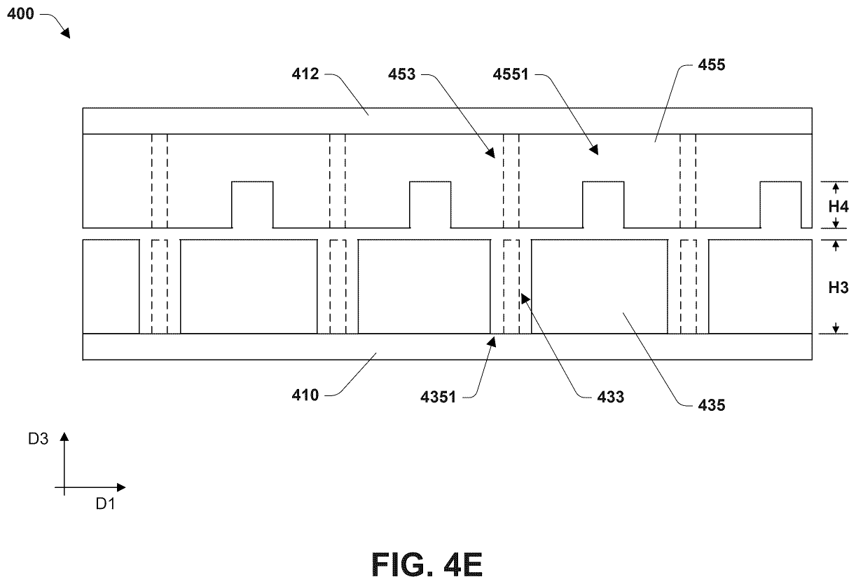

FIGS. 4A, 4B, 4C, 4D, and 4E illustrate diagrams of an integrated circuit device 400, in accordance with some embodiments. The integrated circuit device 400 can be an embodiment of the integrated circuit device 200 described with reference to FIGS. 2A-2G and is similar in most respects to the integrated circuit device 300 described with reference to FIGS. 3A-3C. Similar elements can be labeled with similar reference numerals. For example, a pixel portion 42 and the pixel portion 32 may be similar elements, a first shielding structure portion 430 and the first shielding structure portion 330 may be similar elements, and so on.

In FIG. 4A, a first wafer 40 includes a first substrate 410, which can be similar in most respects to the semiconductor substrate or “first wafer” 102. The first wafer 102 can be an embodiment of the first wafer 40. In some embodiments, the first wafer 40 includes a plurality of array structure portions or pixel portions 42 positioned therein, thereon or both. The pixel portions 42 can be arranged in pixel rows that extend along the first direction D1 and are arranged along the second direction D2. The pixel portions 42 can be arranged in pixel columns that extend along the second direction D2 and are arranged along the first direction D1. Each of the pixel portions 42 includes a respective via structure portion 420 therein.

A first shielding structure portion 430 is positioned on and/or in the substrate 410. Each of the pixel portions 42 can include a first shield wall portion 431, a second shield wall portion 433, a third shield wall portion 435 and a fourth shield wall portion 437 of the first shielding structure portion 430, which can be referred to collectively as the shield wall portions 431, 433, 435, 437. Each of the shield wall portions 431, 433, 435, 437 can be positioned between an immediately adjacent pair of the pixel portions 42.

The second wafer 41 includes a second substrate 412, which can be similar in most respects to the semiconductor substrate or “second wafer” 104. The second wafer 104 can be an embodiment of the second wafer 41. In some embodiments, the second wafer 41 includes a plurality of array structure portions or pixel portions 44 positioned therein, thereon or both. The pixel portions 44 can be arranged in pixel rows that extend along the first direction D1 and are arranged along the second direction D2. The pixel portions 44 can be arranged in pixel columns that extend along the second direction D2 and are arranged along the first direction D1. Each of the pixel portions 44 includes a respective via structure portion 440 therein.

A second shielding structure portion 450 is positioned on and/or in the substrate 412. Each of the pixel portions 44 can include a first shield wall portion 451, a second shield wall portion 453, a third shield wall portion 455 and a fourth shield wall portion 457 of the second shielding structure portion 450, which can be referred to collectively as the shield wall portions 451, 453, 455, 457. Each of the shield wall portions 451, 453, 455, 457 can be positioned between an immediately adjacent pair of the pixel portions 44.

FIG. 4C depicts an embodiment in which the first height H3 of first openings 4351 (e.g., similar to the first openings 3351) and the second height H4 of second openings 4551 (e.g., similar to the second openings 3551) are each the same as height of the respective first shielding structure portion 430 and second shielding structure portion 450. Namely, the first openings 4351 have the first height H3 and extend fully through the first shielding structure portion 430, exposing the first substrate 410. Similarly, the second openings 4551 have the second height H4 and extend fully through the second shielding structure portion 450, exposing the second substrate 412. In some embodiments, portions of the first substrate 410 exposed by the first openings 4351 and portions of the second substrate 412 exposed by the second openings 4551 may have concave profile.

FIG. 4D depicts an embodiment in which the first height H3 of the first openings 4351 is less than that of the first shielding structure portion 430, and the second height H4 of second openings 4551 is the same as height of the second shielding structure portion 450. Namely, the first openings 4351 have the first height H3 and extend partially through the first shielding structure portion 430, not exposing the first substrate 410. The second openings 4551 have the second height H4 and extend fully through the second shielding structure portion 450, exposing the second substrate 412. As depicted in FIG. 4D, the first openings 4351 extend only partially through the first shielding structure portion 430 while the second openings 4551 extend fully through the second shielding structure portion 450.

FIG. 4E depicts an embodiment in which the first height H3 of the first openings 4351 is the same as that of the first shielding structure portion 430 and the second height H4 of the second openings 4551 is less than the height of the second shielding structure portion 450. Namely, the first openings 4351 have the first height H3 and extend fully through the first shielding structure portion 430, exposing the first substrate 410. The second openings 4551 have the second height H4 and extend partially through the second shielding structure portion 450, not exposing the second substrate 412. As depicted in FIG. 4E, the first openings 4351 extend fully through the first shielding structure portion 430 while the second openings 4551 extend only partially through the second shielding structure portion 450.

It should be understood that the embodiments of FIGS. 4C-4E may combined. For example, some of the first openings 4351 may extend partially through the first shielding structure portion 430 while others of the first openings 4351 may extend fully through the first shielding structure portion 430. In another example, some of the second openings 4551 may extend partially through the second shielding structure portion 450 while others of the second openings 4551 may extend fully through the second shielding structure portion 450.

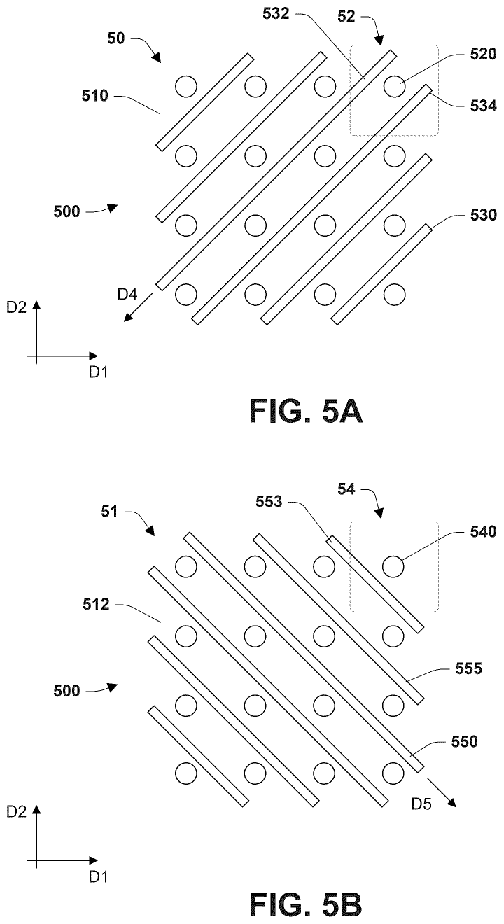

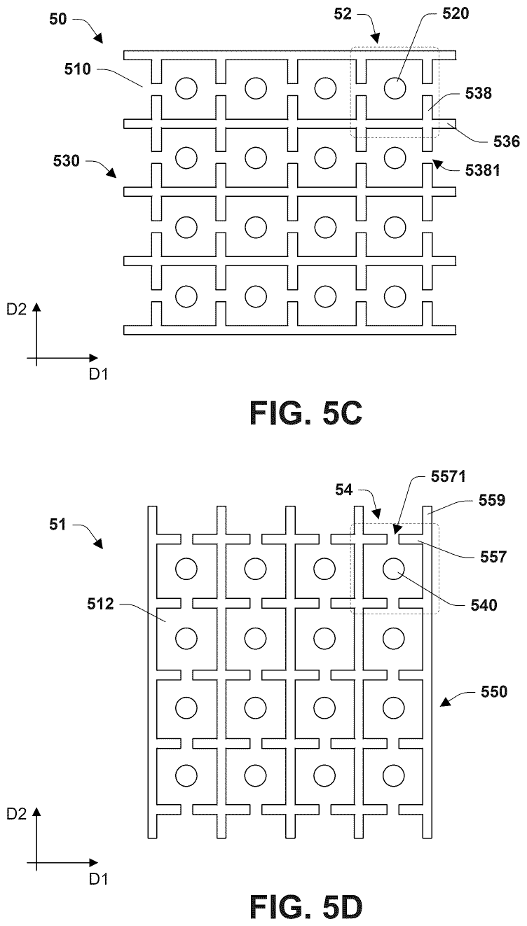

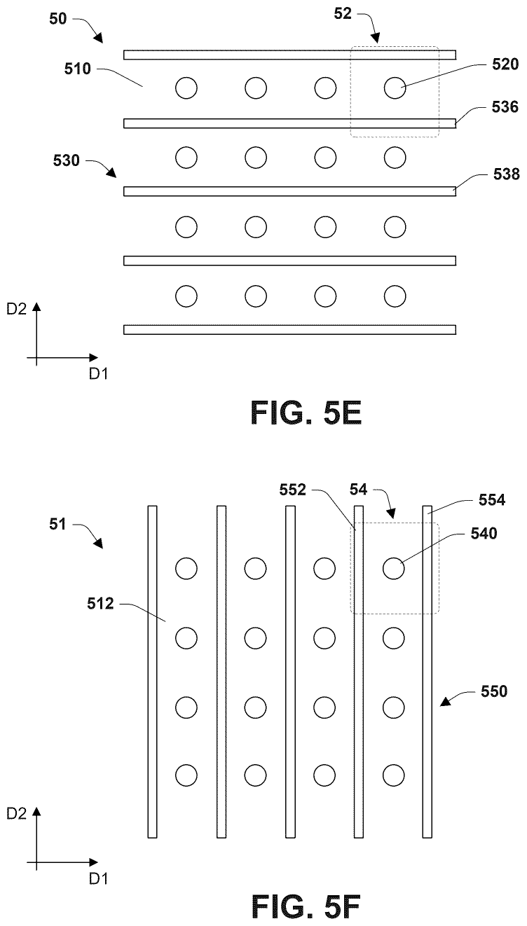

FIGS. 5A, 5B, 5C, 5D, 5E, and 5F illustrate diagrams of an integrated circuit device 500, in accordance with some embodiments. The integrated circuit device 500 can be an embodiment of the integrated circuit device 200 described with reference to FIGS. 2A-2G and is similar in many respects to the integrated circuit devices 300 described with reference to FIGS. 3A-4E. Similar elements can be labeled with similar reference numerals. For example, a pixel portion 52 and the pixel portions 32, 42 may be similar elements, a first shielding structure portion 530 and the first shielding structure portions 330, 430 may be similar elements, and so on.

In FIGS. 5A and 5B, a first wafer 50 includes a first substrate 510, which can be similar in most respects to the semiconductor substrate or “first wafer” 102. The first wafer 102 can be an embodiment of the first wafer 50. In some embodiments, the first wafer 50 includes a plurality of array structure portions or pixel portions 52 positioned therein, thereon or both. The pixel portions 52 can be arranged in pixel rows that extend along the first direction D1 and are arranged along the second direction D2. The pixel portions 52 can be arranged in pixel columns that extend along the second direction D2 and are arranged along the first direction D1. Each of the pixel portions 52 includes a respective via structure portion 520 therein.

A first shielding structure portion 530 is positioned on and/or in the substrate 510. Each of the pixel portions 52 can include a first shield wall portion 532 and a second shield wall portion 534 adjacent thereto. The first shield wall portion 532 and the second shield wall portion 534 may extend along a fourth direction D4 that has an angular offset to the first direction D1 and the second direction D2. In some embodiments, the angular offset is in a range of about 40 degrees to about 50 degrees, such as about 45 degrees. For example, the first and second shield wall portions 532, 534 can extend diagonally through the pixel rows and pixel columns.

The second wafer 51 includes a second substrate 512, which can be similar in most respects to the semiconductor substrate or “second wafer” 104. The second wafer 104 can be an embodiment of the second wafer 51. In some embodiments, the second wafer 51 includes a plurality of array structure portions or pixel portions 54 positioned therein, thereon or both. The pixel portions 54 can be arranged in pixel rows that extend along the first direction D1 and are arranged along the second direction D2. The pixel portions 54 can be arranged in pixel columns that extend along the second direction D2 and are arranged along the first direction D1. Each of the pixel portions 54 includes a respective via structure portion 540 therein.

A second shielding structure portion 550 is positioned on and/or in the substrate 512. Each of the pixel portions 54 can include a first shield wall portion 553 and a second shield wall portion 555 adjacent thereto. The first shield wall portion 553 and the second shield wall portion 555 may extend along a fifth direction D5 that is transverse (e.g., perpendicular to) the fourth direction D4. The first and second shield wall portions 553, 555 can extend diagonally through the pixel rows and pixel columns.

When bonded, the first shielding structure portion 530 and the second shielding structure portion 550 may be connected at overlapping regions thereof. As a result, a shielding structure including the first and second shielding structure portions 530, 550 may have diamond or rhombus shape that laterally surrounds each pixel that includes the pixel portions 52, 54. The first and second shield wall portions 532, 534 and the first and second shield wall portions 553, 555 may each be a continuous, unbroken wall that does not define openings therein. Namely, openings that form exhaust paths in the first and second shielding structure portions 530, 550 may be defined by immediately adjacent walls of the first and second shielding structure portions 530, 550. For example, a first opening may be defined between the first shield wall portion 532, the second shield wall portion 534, and the first shield wall portion 553. In another example, a second opening may be defined between the first shield wall portion 532, the second shield wall portion 534, and the second shield wall portion 555.

In FIGS. 5C and 5D, the first wafer 50 can include a first shielding structure portion 530 and the second wafer 51 can include a second shielding structure portion 550. The first shielding structure portion 530 can include first shield wall portions 536 that extend in the first direction D1 and are arranged in the second direction D2 and second shield wall portions 538 that extend in the second direction D2 and are arranged in the first direction D1. The first shielding structure portion 530 can include first openings 5381 defined in the second shield wall portions 538. The first shield wall portions 536 can be continuous and unbroken in the first direction D1.

The second shielding structure portion 550 can include first walls 557 that extend in the first direction D1 and are arranged in the second direction D2 and second walls 559 that extend in the second direction D2 and are arranged in the first direction D1. The second shielding structure portion 550 can include second openings 5571 defined in the first walls 557. The second walls 559 can be continuous and unbroken in the second direction D2.

As described with reference to FIGS. 2A-2G, the first openings 5381, the second openings 5571, or both can extend partially or fully through the respective first shielding structure portion 530 and second shielding structure portion 550.

In the embodiments described with reference to FIGS. 2A-5F, a first area of the plurality of openings in the shielding structure can include area, for example, of the openings defined in or defined by a first shielding structure portion of a first wafer and a second shielding structure portion of a second wafer bonded to the first wafer. For example, the first shielding structure portion 330 described with reference to FIG. 3C has first openings 3351 defined therein and the second shielding structure portion 350 has second openings 3551 defined therein. The first area can include area of the first openings 3351 and the second openings 3551.

A second area of the shielding structure can include area, for example, of the first shielding structure portion and the second shielding portion. For example, the second area can include area of the first shielding structure portion 330 and the second shielding structure portion 350. The second area can be inclusive of the openings defined in the shielding structure or can be exclusive of the openings defined in the shielding structure.

An area ratio can be the first area over the second area. Namely, the area ratio can be an area concentration of the openings as a function of total area of the shielding structure (inclusive or exclusive of the openings). In some embodiments, the area ratio or area concentration is in a range of about 0.01 to about 1, such as about 0.1 to about 0.5. The area ratio being about 1 can be associated with, for example, the structures described with reference to FIGS. 5A and 5B, FIGS. 5E and 5F, or both. Namely, area of openings may be about equal to area of the shielding structure exclusive of the openings. Below an area concentration of the openings of about 0.01, gas exhausting performance of the shielding structure may be insufficient to prevent formation of bubbles. Namely, when the openings comprise less than about 1% of area of the shielding structure, gas may remain, which can result in formation of bubbles.

In FIGS. 5E and 5F, the first shielding structure portion 530 is positioned on and/or in the substrate 510. Each of the pixel portions 52 can include a first shield wall portion 536 and a second shield wall portion 538 adjacent thereto. The first shield wall portion 536 and the second shield wall portion 538 may extend along the first direction D1 and be arranged along the second direction D2. For example, the first and second shield wall portions 536, 538 can extend horizontally through the pixel rows and pixel columns.

The second shielding structure portion 550 is positioned on and/or in the substrate 512. Each of the pixel portions 54 can include a first shield wall portion 552 and a second shield wall portion 554 adjacent thereto. The first shield wall portion 552 and the second shield wall portion 554 may extend along the second direction D2 and be arranged along the first direction D1. The first and second shield wall portions 552, 554 can extend vertically through the pixel rows and pixel columns.

When bonded, the first shielding structure portion 530 and the second shielding structure portion 550 may be connected at overlapping regions thereof. As a result, a shielding structure including the first and second shielding structure portions 530, 550 may have square or rectangular shape that laterally surrounds each pixel that includes the pixel portions 52, 54. The first and second shield wall portions 536, 538 and the first and second shield wall portions 552, 554 may each be a continuous, unbroken wall that does not define openings therein. Namely, openings that form exhaust paths in the first and second shielding structure portions 530, 550 may be defined by immediately adjacent walls of the first and second shielding structure portions 530, 550. For example, a first opening may be defined between the first shield wall portion 536, the second shield wall portion 538, and the first shield wall portion 552. In another example, a second opening may be defined between the first shield wall portion 536, the second shield wall portion 538, and the second shield wall portion 554.

A method 600 is illustrated in FIG. 6 in accordance with some embodiments.

At 602, the method 600 includes providing a first wafer having a first interconnect structure thereon, the first interconnect structure including a first portion of a guard ring structure. In some embodiments, providing the first wafer includes providing the first wafer including a plurality of pixels that are arranged in a plurality of pixel rows that extend along a first direction and are arranged along a second direction transverse the first direction. In some embodiments, providing the first wafer having the first interconnect structure including the first portion of the guard ring structure includes providing the first interconnect structure including: a first via portion of the via structure, the first via portion extending to a first height above an upper surface of a topmost layer of the first interconnect structure; and the first portion of the guard ring structure, the first portion extending to a second height above the upper surface of the topmost layer of the first interconnect structure, the second height exceeding the first height by a dimension in a range of about 1 Angstrom to about 10 Angstroms.

At 604, the method 600 includes providing a second wafer having a second interconnect structure thereon, the second interconnect structure including a second portion of the guard ring structure.

At 606, 608 and 610, the method 600 includes forming a bonded structure by bonding the first wafer to the second wafer.

At 606, the method 600 includes forming a hybrid bond between the first interconnect structure and the second interconnect structure.

At 608, the method 600 includes forming a via structure associated with a first pixel of a plurality of pixels, the via structure extending through the first interconnect structure and the second interconnect structure.

At 610, the method 600 includes forming the guard ring structure adjacent the via structure, the guard ring structure including a first wall that extends perpendicular to a major surface of the first wafer and a second wall that extends perpendicular to the major surface of the first wafer, each of the first wall and the second wall defining a respective opening therein.

In some embodiments, forming the guard ring structure includes forming a metal bond between the first portion of the guard ring structure and the second portion of the guard ring structure, wherein the first portion defines a plurality of first openings therein and the second portion defines a plurality of second openings therein.

In some embodiments, forming the guard ring structure includes forming the guard ring structure including: the first wall that extends along a third direction that has an angular offset from the first direction that is in a range of about 40 degrees to about 50 degrees; and the second wall that extends along a fourth direction that is transverse the third direction.

In some embodiments, the first portion of the guard ring structure includes a plurality of first walls including the first wall, the plurality of first walls extending along the first direction, being arranged along the second direction and being physically separated from each other. In some embodiments, the second portion of the guard ring structure includes a plurality of second walls including the second wall, the plurality of second walls extending along the second direction, being arranged along the first direction and being physically separated from each other.

A method 700 is illustrated in FIG. 7 in accordance with some embodiments.

At 702, the method 700 includes providing a first substrate having a first interconnect structure.

At 704, the method 700 includes providing a second substrate having a second interconnect structure.

At 706, the method 700 includes forming a pre-shielding structure by bonding a first portion of a shielding structure to a second portion of the shielding structure, the first portion being in the first interconnect structure and the second portion being in the second interconnect structure.

At 708, the method 700 includes, during bonding, exhausting gas via respective openings in the first portion and the second portion.

At 710, the method 700 includes forming the shielding structure by annealing the pre-shielding structure.

At 712, the method 700 includes, during annealing, exhausting gas via the openings in the pre-shielding structure.

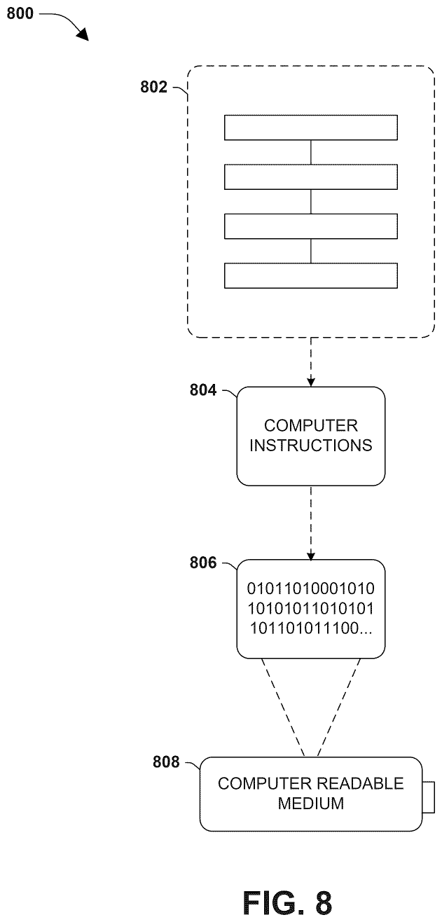

One or more embodiments involve a computer-readable medium comprising processor-executable instructions configured to implement one or more of the techniques presented herein. An exemplary computer-readable medium is illustrated in FIG. 8, wherein the embodiment 800 comprises a computer-readable medium 808 (e.g., a CD-R, DVD-R, flash drive, a platter of a hard disk drive, etc.), on which is encoded computer-readable data 806. This computer-readable data 806 in turn comprises a set of processor-executable computer instructions 804 configured to implement one or more of the principles set forth herein when executed by a processor. In some embodiments 800, the processor-executable computer instructions 804 are configured to implement a method 802, such as at least some of the aforementioned method(s) when executed by a processor. In some embodiments, the processor-executable computer instructions 804 are configured to implement a system, such as at least some of the one or more aforementioned system(s) when executed by a processor. Many such computer-readable media may be devised by those of ordinary skill in the art that are configured to operate in accordance with the techniques presented herein.

In some embodiments, a device is provided. The device includes: a first substrate; a first interconnect structure on the first substrate; a second substrate; a second interconnect structure on the second substrate, the first substrate being bonded to the second substrate by a hybrid bond between the first interconnect structure and the second interconnect structure; a via structure that extends through the first interconnect structure and the second interconnect structure; and a shield structure that is adjacent to the via structure. The shield structure includes: at least four walls on four respective sides of the via structure; and at least two openings in at least two respective walls of the at least four walls.

In some embodiments, a device is provided. The device comprises: a first integrated circuit die including a plurality of pixels arranged in a plurality of pixel rows and a plurality of pixel columns; a second integrated circuit die bonded to the first integrated circuit die by a hybrid bond; a guard ring structure that is adjacent the plurality of pixels, the guard ring structure including: a first portion in the first integrated circuit die; and a second portion in the second integrated circuit die and bonded to the first portion. The device includes: a plurality of openings in the guard ring structure; and an exhaust path that extends fully through the guard ring structure via the plurality of openings.

In some embodiments, a method is provided. The method comprising: providing a first wafer having a first interconnect structure thereon; providing a second wafer having a second interconnect structure thereon; and forming a bonded structure by bonding the first wafer to the second wafer including: forming a hybrid bond between the first interconnect structure and the second interconnect structure; forming a via structure associated with a pixel, the via structure extending through the first interconnect structure and the second interconnect structure; and forming a guard ring adjacent the via structure, the guard ring including a wall that extends perpendicular to a major surface of the first wafer, the wall defining an opening therein.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” and/or the like is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A device, comprising:
a first substrate;
a first interconnect structure on the first substrate;
a second substrate;
a second interconnect structure on the second substrate, the first substrate being bonded to the second substrate by a hybrid bond between the first interconnect structure and the second interconnect structure;
a via structure that extends through the first interconnect structure and the second interconnect structure; and
a shield structure that is adjacent to the via structure, the shield structure including:
at least four walls on four respective sides of the via structure; and
at least two openings in at least two respective walls of the at least four walls.

2. The device of claim 1, wherein the shield structure includes:
a first shielding structure portion in the first interconnect structure; and
a second shielding structure portion in the second interconnect structure, the second shielding structure portion being in direct contact with the first shielding structure portion.

3. The device of claim 2, wherein:
the first shielding structure portion defines a plurality of first openings in first walls thereof; and
the second shielding structure portion defines a plurality of second openings in second walls thereof.

4. The device of claim 3, wherein the first walls extend to a first height and each of the plurality of first openings extends to a second height, the first height exceeding the second height.

5. The device of claim 3, wherein the first walls extend to a first height and each of the plurality of first openings extends to a second height, the first height being equal to the second height.

6. The device of claim 1, wherein the at least two respective walls are on opposite sides of the via structure from each other.

7. The device of claim 1, wherein the at least two respective walls intersect each other.

8. A device comprising:
a first integrated circuit die including a plurality of pixels arranged in a plurality of pixel rows that extend along a first direction and are arranged along a second direction transverse the first direction;
a second integrated circuit die bonded to the first integrated circuit die by a hybrid bond;
a guard ring structure that is adjacent the plurality of pixels, the guard ring structure including:
a first portion in the first integrated circuit die; and
a second portion in the second integrated circuit die and bonded to the first portion;
a plurality of openings in the guard ring structure; and
an exhaust path that extends fully through the guard ring structure via the plurality of openings.

9. The device of claim 8, wherein each of the plurality of pixels is adjacent four walls of the guard ring structure, at least two of the four walls defining a respective one of the plurality of openings therein.

10. The device of claim 8, wherein the exhaust path extends along the first direction.

11. The device of claim 8, wherein the exhaust path extends along the first direction and the second direction.

12. The device of claim 8, wherein the exhaust path extends along a third direction that has an angular offset from the first direction in a range of about 40 degrees to about 50 degrees.

13. The device of claim 8, further comprising:
a second exhaust path that extends fully through the guard ring structure, the second exhaust path being isolated from the exhaust path.

14. The device of claim 13, wherein an area ratio of first area of the plurality of openings over second area of the guard ring structure is in a range of about 0.1 to about 1.

15. A method, comprising:
providing a first wafer having a first interconnect structure thereon, the first interconnect structure including a first portion of a guard ring structure;
providing a second wafer having a second interconnect structure thereon, the second interconnect structure including a second portion of the guard ring structure; and
forming a bonded structure by bonding the first wafer to the second wafer including:
forming a hybrid bond between the first interconnect structure and the second interconnect structure;
forming a via structure associated with a first pixel of a plurality of pixels, the via structure extending through the first interconnect structure and the second interconnect structure; and
forming the guard ring structure adjacent the via structure, the guard ring structure including a first wall that extends perpendicular to a major surface of the first wafer and a second wall that extends perpendicular to the major surface of the first wafer, each of the first wall and the second wall defining a respective opening therein.

16. The method of claim 15, wherein forming the guard ring structure includes:
forming a metal bond between the first portion of the guard ring structure and the second portion of the guard ring structure, wherein the first portion defines a plurality of first openings therein and the second portion defines a plurality of second openings therein.

17. The method of claim 16, wherein providing the first wafer includes providing the first wafer including the plurality of pixels that are arranged in a plurality of pixel rows that extend along a first direction and are arranged along a second direction transverse the first direction.

18. The method of claim 17, wherein forming the guard ring structure includes forming the guard ring structure including:
the first wall that extends along a third direction that has an angular offset from the first direction that is in a range of about 40 degrees to about 50 degrees; and
the second wall that extends along a fourth direction that is transverse the third direction.

19. The method of claim 17, wherein:
the first portion of the guard ring structure includes a plurality of first walls including the first wall, the plurality of first walls extending along the first direction, being arranged along the second direction and being physically separated from each other; and
the second portion of the guard ring structure includes a plurality of second walls including the second wall, the plurality of second walls extending along the second direction, being arranged along the first direction and being physically separated from each other.

20. The method of claim 15, wherein providing the first wafer having the first interconnect structure including the first portion of the guard ring structure includes providing the first interconnect structure including:
a first via portion of the via structure, the first via portion extending to a first height above an upper surface of a topmost layer of the first interconnect structure; and
the first portion of the guard ring structure, the first portion extending to a second height above the upper surface of the topmost layer of the first interconnect structure, the second height exceeding the first height by a dimension in a range of about 1 Angstrom to about 10 Angstroms.
